(19) United States
(12) Patent Application Publication
(10) Pub. No.: US 2025/0359291 A1
(43) Pub. Date: Nov. 20, 2025

(54) CONTACT PLUGS WITH REDUCED R/C AND THE METHODS OF FORMING THE SAME

(71) Applicant: Taiwan Semiconductor Manufacturing Co., Ltd., Hsinchu (TW)

(72) Inventors: Min-Hsiu Hung, Tainan City (TW); Chun-I Tsai, Hsinchu (TW); Chih-Wei Chang, Hsinchu (TW); Ming-Hsing Tsai, Chu-Pei City (TW); Syun-Ming Jang, Hsinchu (TW); Wei-Jen Lo, Hsinchu (TW); Wei-Jung Lin, Hsinchu (TW); Yu-Ting Wen, Taichung City (TW); Kai-Chieh Yang, Kaohsiung City (TW)

(21) Appl. No.: 19/285,360

(22) Filed: Jul. 30, 2025

Related U.S. Application Data
(63) Continuation of application No. 18/488,393, filed on Oct. 17, 2023.
(60) Provisional application No. 63/506,903, filed on Jun. 8, 2023.

(51) Int. Cl. H10D 84/03; H01L 21/321; H10D 30/01; H10D 64/01; H10D 84/01; H10D 84/85

(52) U.S. Cl. CPC H10D 84/038; H01L 21/32115; H10D 30/024; H10D 64/017; H10D 84/017; H10D 84/0184; H10D 84/0193; H10D 84/853

(57) ABSTRACT

A method includes forming a contact spacer on a sidewall of an inter-layer dielectric, wherein the contact spacer encircles a contact opening, forming a silicide region in the opening and on a source/drain region, depositing an adhesion layer extending into the contact opening, and performing a treatment process, so that the contact spacer is treated. The treatment process is selected from the group consisting of an oxidation process, a carbonation process, and combinations thereof. The method further includes depositing a metal barrier over the adhesion layer, depositing a metallic material to fill the contact opening, and performing a planarization process to remove excess portions of the metallic material over the inter-layer dielectric.

### PRIORITY CLAIM AND CROSS-REFERENCE

This application is a continuation of U.S. patent application Ser. No. 18/488,393, filed on Oct. 17, 2023 and entitled “CONTACT PLUGS WITH REDUCED R/C AND THE METHODS OF FORMING THE SAME,” which application claims the benefit of U.S. Provisional Application No. 63/506,903, filed on Jun. 8, 2023, and entitled “Low R*C Plug Manufacturing Method via Surface Modification Treatment,” which applications are hereby incorporated herein by reference.

### BACKGROUND

In the manufacturing of integrated circuits, source/drain contact plugs are used for connecting to the source and drain regions of transistors. The source/drain contact plugs are typically connected to source/drain silicide regions. The formation of the source/drain contact plugs includes forming contact openings in an inter-layer dielectric, depositing a metal layer extending into the contact openings, and then performing an anneal process to react the metal layer with the silicon/germanium of the source/drain regions. The source/drain contact plugs are then formed in the remaining contact openings. The gate contact plugs are also formed to connect to the gates of the transistors.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-8, 9A, 9B, 9C, and 23 illustrate the views of intermediate stages in the formation of Fin Field-Effect Transistors (FinFETs) in accordance with some embodiments.

FIGS. 10-15 illustrate the cross-sectional views of intermediate stages in the formation of contact plugs in accordance with some embodiments.

FIGS. 16A, 16B, 17A, 17B, 18A, 18B, 19A, 19B, 20A, 20B, 21A, 21B, 22A, and 22B illustrate the cross-sectional views of intermediate stages in the formation of contact plugs in accordance with alternatively embodiments.

FIG. 24 illustrates some results in accordance with some embodiments.

FIGS. 25 and 26 illustrate the top views of some structures that can adopt the contact plugs in accordance with the embodiments of the present disclosure.

FIG. 27 illustrates a process flow for forming FinFETs in accordance with some embodiments.

FIG. 28 illustrates a process flow for forming a contact plug in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Transistors including contact spacers having reduced dielectric constant values and contact plugs are provided in accordance with various embodiments. The corresponding formation processes are also provided. In accordance with some embodiments, contact spacers are formed, and are treated to lower their dielectric constant values (k values). This results in the reduction of parasitic capacitance values in the transistors. Also, through the treatment, the deposition selectivity is improved when a metal is deposited for forming the contact plugs. It is appreciated that although the formation of Fin Field-Effect Transistors (FinFETs) is used as an example to explain the concept of the present disclosure, other types of transistors such as planar transistors, Gate-All-Around (GAA) transistors, Complementary Field-Effect Transistors (CFETs), and the corresponding contact plugs may also adopt the concept of the present disclosure.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

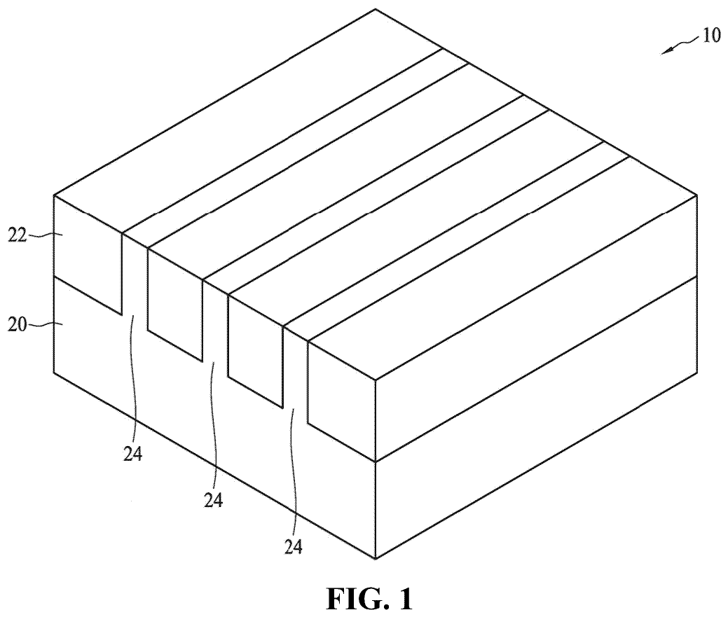

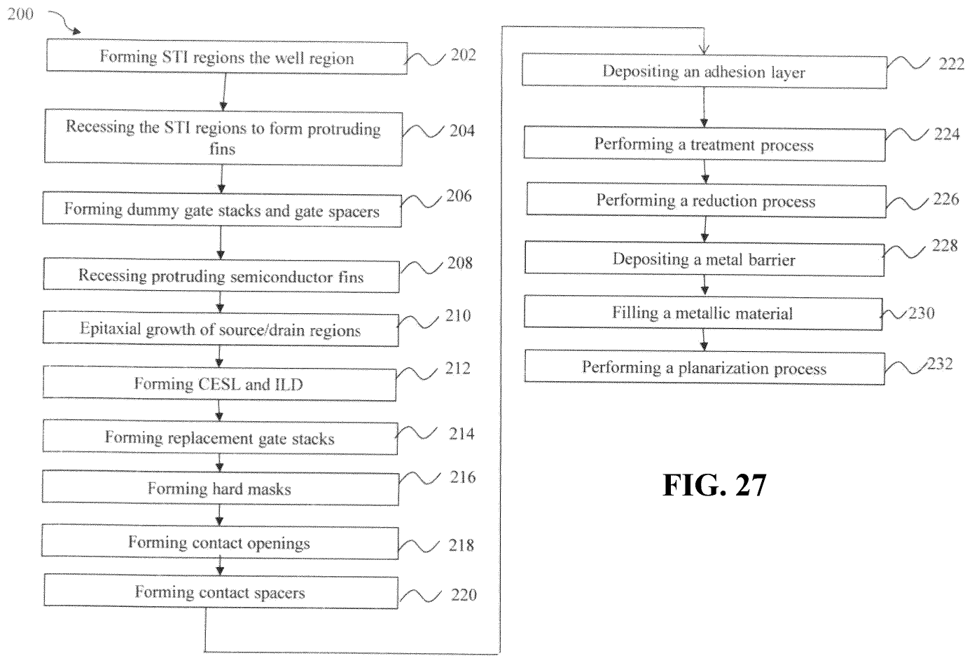

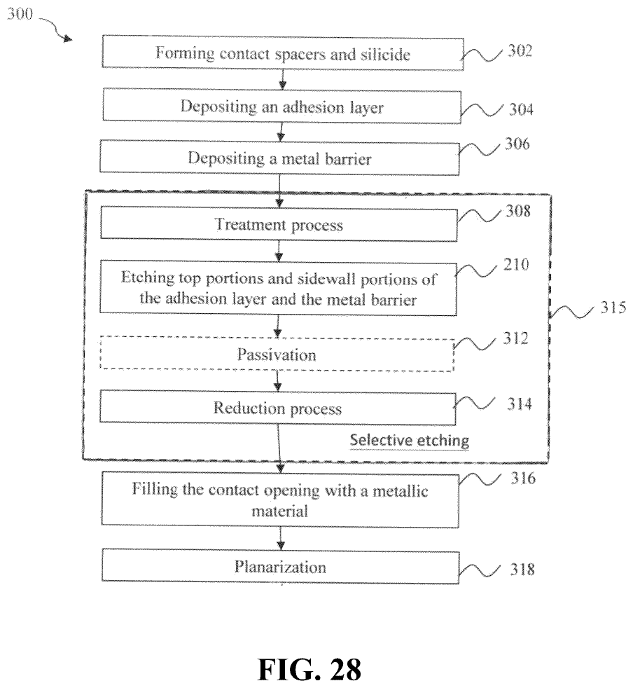

FIGS. 1-8, 9A, 9B, 9C, 10-15, and 23 illustrate the views of intermediate stages in the formation of Fin Field-Effect Transistors (FinFETs), contact spacers, and contact plugs in accordance with some embodiments. The processes shown in these figures are also reflected schematically in the process flow 200 as shown in FIG. 27 and the process flow 300 as shown in FIG. 28.

FIG. 1 illustrates a perspective view of an initial structure formed on wafer 10. Wafer 10 includes substrate 20. Substrate 20 may be a semiconductor substrate, which may be a silicon substrate, a silicon germanium substrate, or a substrate formed of other semiconductor materials. Substrate 20 may be doped with a p-type or an n-type impurity. Isolation regions 22 such as Shallow Trench Isolation (STI) regions may be formed to extend from a top surface of substrate 20 into substrate 20. The respective process is illustrated as process 202 in the process flow 200 shown in FIG. 27. The portions of substrate 20 between neighboring STI regions 22 are referred to as semiconductor strips 24. The top surfaces of semiconductor strips 24 and the top surfaces of STI regions 22 may be substantially level with each other in accordance with some embodiments.

In accordance with some embodiments of the present disclosure, semiconductor strips 24 are parts of the original substrate 20, and hence the material of semiconductor strips 24 is the same as that of substrate 20. In accordance with alternative embodiments of the present disclosure, semiconductor strips 24 are replacement strips formed by etching the portions of substrate 20 between STI regions 22 to form recesses, and performing an epitaxy to regrow another semiconductor material in the recesses. Accordingly, semiconductor strips 24 are formed of a semiconductor material different from that of substrate 20. In accordance with some embodiments, semiconductor strips 24 are formed of silicon germanium, silicon carbon, or a III-V compound semiconductor material.

STI regions 22 may include a liner oxide (not shown), which may be a thermal oxide formed through the thermal oxidation of a surface layer of substrate 20. The liner oxide may also be a deposited silicon oxide layer formed using, for example, Atomic Layer Deposition (ALD), High-Density Plasma Chemical Vapor Deposition (HDPCVD), Chemical Vapor Deposition (CVD), or the like. STI regions 22 may also include a dielectric material over the liner oxide, wherein the dielectric material may be formed using Flowable Chemical Vapor Deposition (FCVD), spin-on coating, or the like.

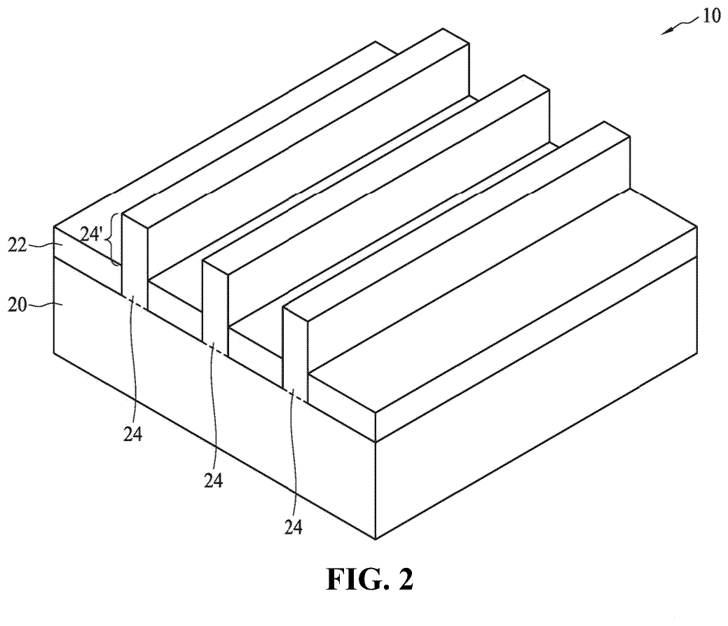

Referring to FIG. 2, STI regions 22 are recessed, so that the top portions of semiconductor strips 24 protrude higher than the top surfaces 22A of the remaining portions of STI regions 22 to form protruding fins 24′. The respective process is illustrated as process 204 in the process flow 200 shown in FIG. 27. The etching may be performed using a dry etching process, wherein HF₃ and NH₃ are used as the etching gases. During the etching process, plasma may be generated. Argon may also be included. In accordance with alternative embodiments of the present disclosure, the recessing of STI regions 22 is performed using a wet etching process. The etching chemical may include HF, for example.

In above-illustrated embodiments, the fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins.

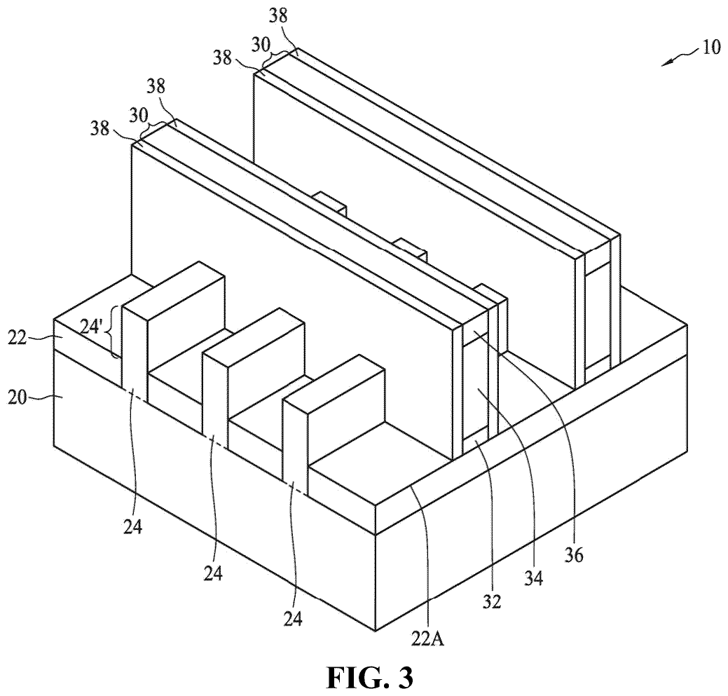

Referring to FIG. 3, dummy gate stacks 30 are formed to extend on the top surfaces and the sidewalls of (protruding) fins 24′. The respective process is illustrated as process 206 in the process flow 200 shown in FIG. 27. Dummy gate dielectrics 32 may be formed of a dielectric material such as silicon oxide, and may be formed through a thermal oxidation process, a chemical oxidation process, a deposition process, or the like. Dummy gate stacks 30 may include dummy gate dielectrics 32 and dummy gate electrodes 34 over the respective dummy gate dielectrics 32. Dummy gate electrodes 34 may be formed, for example, using polysilicon, amorphous silicon, amorphous carbon, and other materials may also be used. Each of dummy gate stacks 30 may also include one (or a plurality of) hard mask layer 36 over dummy gate electrodes 34. Hard mask layers 36 may be formed of silicon nitride, silicon oxide, silicon oxy-nitride, or multi-layers thereof.

Next, gate spacers 38 are formed on the sidewalls of dummy gate stacks 30. In accordance with some embodiments of the present disclosure, gate spacers 38 are formed of a dielectric material(s) such as silicon nitride, silicon carbo-nitride, or the like, and may have a single-layer structure or a multi-layer structure including a plurality of dielectric layers.

An etching step is then performed to etch the portions of protruding fins 24′ that are not covered by dummy gate stack 30 and gate spacers 38, resulting in the structure shown in FIG. 4. The respective process is illustrated as process 208 in the process flow 200 shown in FIG. 27. The recessing may be anisotropic, and hence the portions of fins 24′ directly underlying dummy gate stacks 30 and gate spacers 38 are protected, and are not etched. The top surfaces of the recessed semiconductor strips 24 may be lower than the top surfaces 22A of STI regions 22 in accordance with some embodiments. The spaces left by the etched protruding fins 24′ and semiconductor strips 24 are referred to as recesses 40. Recesses 40 are located on the opposite sides of dummy gate stacks 30.

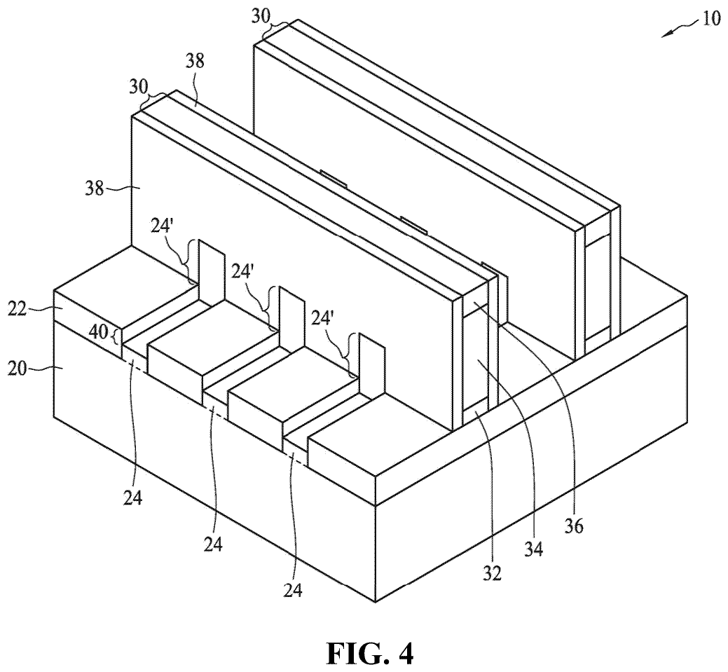

Next, as shown in FIG. 5, epitaxy regions (source/drain regions) 42 are formed by selectively growing (through epitaxy) a semiconductor material in recesses 40. The respective process is illustrated as process 210 in the process flow 200 shown in FIG. 27. Depending on whether the resulting FinFET is a p-type FinFET or an n-type FinFET, a p-type or an n-type impurity may be in-situ doped with the proceeding of the epitaxy. For example, when the resulting FinFET is a p-type FinFET, silicon germanium boron (SiGeB), silicon boron (SiB), or the like may be grown. Conversely, when the resulting FinFET is an n-type FinFET, silicon phosphorous (SiP), silicon carbon phosphorous (SiCP), or the like may be grown. In accordance with alternative embodiments of the present disclosure, epitaxy regions 42 comprise III-V compound semiconductors such as GaAs, InP, GaN, InGaAs, InAlAs, GaSb, AlSb, AlAs, AlP, GaP, combinations thereof, or multi-layers thereof.

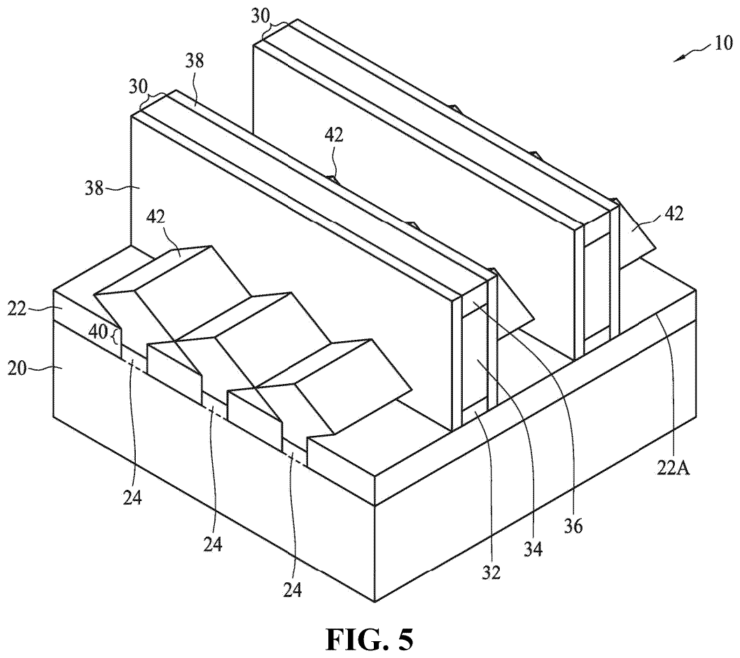

After Recesses 40 are filled with epitaxy regions 42, the further epitaxial growth of epitaxy regions 42 causes epitaxy regions 42 to expand horizontally, and facets may be formed. The further growth of epitaxy regions 42 may also cause neighboring epitaxy regions 42 to merge with each other. Voids (air gaps) 44 may be generated. With the further growth, the top surface of the epitaxy regions 42 may become substantially planar, as shown in FIG. 6.

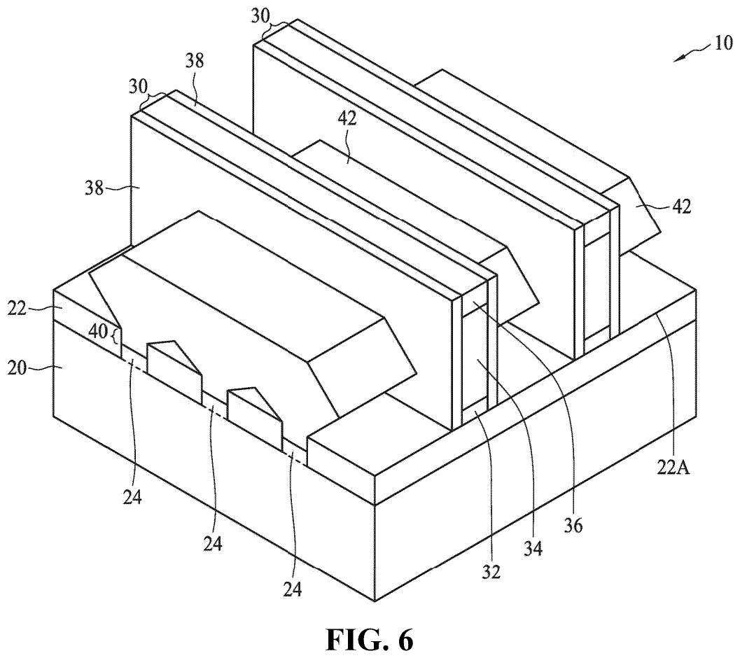

FIG. 7 illustrates a perspective view of the structure after the formation of Contact Etch Stop Layer (CESL) 46 and Inter-Layer Dielectric (ILD) 48. The respective process is illustrated as process 212 in the process flow 200 shown in FIG. 27. CESL 46 may be formed of silicon oxide, silicon nitride, silicon carbo-nitride, or the like, and may be formed using CVD, ALD, or the like. ILD 48 may include a dielectric material formed using, for example, FCVD, spin-on coating, CVD, or another deposition method. ILD 48 may be formed of an oxygen-containing dielectric material, which may be a silicon-oxide based dielectric material such as silicon oxide, Phospho-Silicate Glass (PSG), Boro-Silicate Glass (BSG), Boron-Doped Phospho-Silicate Glass (BPSG), or the like. A planarization process such as a Chemical Mechanical Polish (CMP) process or a mechanical grinding process may be performed to level the top surfaces of ILD 48, dummy gate stacks 30, and gate spacers 38 with each other.

Next, dummy gate stacks 30, which include hard mask layers 36, dummy gate electrodes 34, and dummy gate dielectrics 32, are replaced with replacement gate stacks 56, which include metal gate electrodes 54 and gate dielectrics 52 as shown in FIG. 8. The respective process is illustrated as process 214 in the process flow 200 shown in FIG. 27. When forming replacement gate stacks 56, hard mask layers 36, dummy gate electrodes 34, and dummy gate dielectrics 32 as shown in FIG. 7 are first removed in one or a plurality of etching processes, resulting in trenches/openings to be formed between gate spacers 38. The top surfaces and the sidewalls of protruding semiconductor fins 24′ are exposed to the resulting trenches.

Next, (replacement) gate dielectric layers 52 are formed, which extend into the trenches between gate spacers 38. In accordance with some embodiments of the present disclosure, each of gate dielectric layers 52 includes an Interfacial Layer (IL) as its lower part, which contacts the exposed surfaces of the corresponding protruding fins 24′. The IL may include an oxide layer such as a silicon oxide layer, which is formed through the thermal oxidation of protruding fins 24′, a chemical oxidation process, or a deposition process. Gate dielectric layer 52 may also include a high-k dielectric layer formed over the IL. The high-k dielectric layer may include a high-k dielectric material such as hafnium oxide, lanthanum oxide, aluminum oxide, zirconium oxide, silicon nitride, or the like. The dielectric constant (k-value) of the high-k dielectric material is higher than 3.9, and may be higher than about 7.0. The high-k dielectric layer is formed as a conformal layer, and extends on the sidewalls of protruding fins 24′ and the sidewalls of gate spacers 38. In accordance with some embodiments of the present disclosure, the high-k dielectric layer is formed using ALD or CVD.

Referring further to FIG. 8, gate electrodes 54 are formed over gate dielectrics 52, Gate electrodes 54 include conductive sub-layers. The sub-layers are not shown separately, while the sub-layers are distinguishable from each other. The deposition of the sub-layers may be performed using a conformal deposition method(s) such as ALD or CVD.

The stacked conductive layers may include a diffusion barrier layer and one (or more) work-function layer over the diffusion barrier layer. The diffusion barrier layer may be formed of titanium nitride (TiN), which may (or may not) be doped with silicon. The work-function layer determines the work function of the gate, and includes at least one layer, or a plurality of layers formed of different materials. The material of the work-function layer is selected according to whether the respective FinFET is an n-type FinFET or a p-type FinFET. For example, when the FinFET is an n-type FinFET, the work-function layer may include a TaN layer and a titanium aluminum (TiAl) layer over the TaN layer. When the FinFET is a p-type FinFET, the work-function layer may include a TaN layer and a TiN layer over the TaN layer. After the deposition of the work-function layer(s), a barrier layer, which may be another TiN layer, is formed.

The deposited gate dielectric layers and conductive layers are formed as conformal layers extending into the trenches, and include some portions over ILD 48. Next, a metallic material is deposited to fill the remaining trenches between gate spacers 38. The metallic material may be formed of tungsten or cobalt, for example. Subsequently, a planarization process such as a CMP process or a mechanical grinding process is performed, so that the portions of the gate dielectric layers, conductive sub-layers, and the metallic material over ILD 48 are removed. As a result, metal gate electrodes 54 and gate dielectrics 52 are formed. Gate electrodes 54 and gate dielectrics 52 are in combination referred to as replacement gate stacks 56. The top surfaces of replacement gate stacks 56, gate spacers 38, CESL 46, and ILD 48 may be substantially coplanar at this time.

FIG. 8 also illustrates the formation of (self-aligned) hard masks 58 in accordance with some embodiments. The respective process is illustrated as process 216 in the process flow 200 shown in FIG. 27. The formation of hard mask 58 may include performing an etching process to recess gate stacks 56, so that recesses are formed between gate spacers 38, filling the recesses with a dielectric material, and then performing a planarization process such as a CMP process or a mechanical grinding process to remove excess portions of the dielectric material. Hard masks 58 may be formed of silicon nitride, silicon oxynitride, silicon oxy-carbo-nitride, or the like.

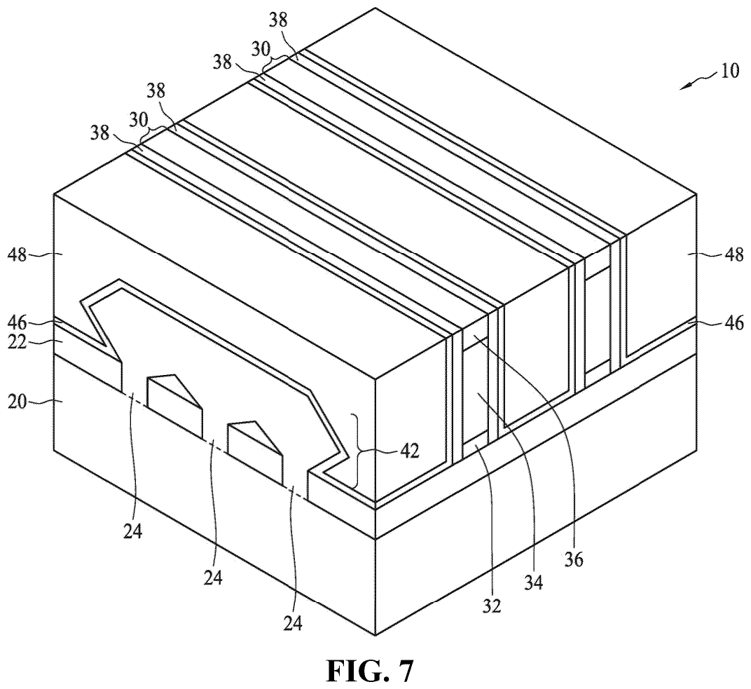

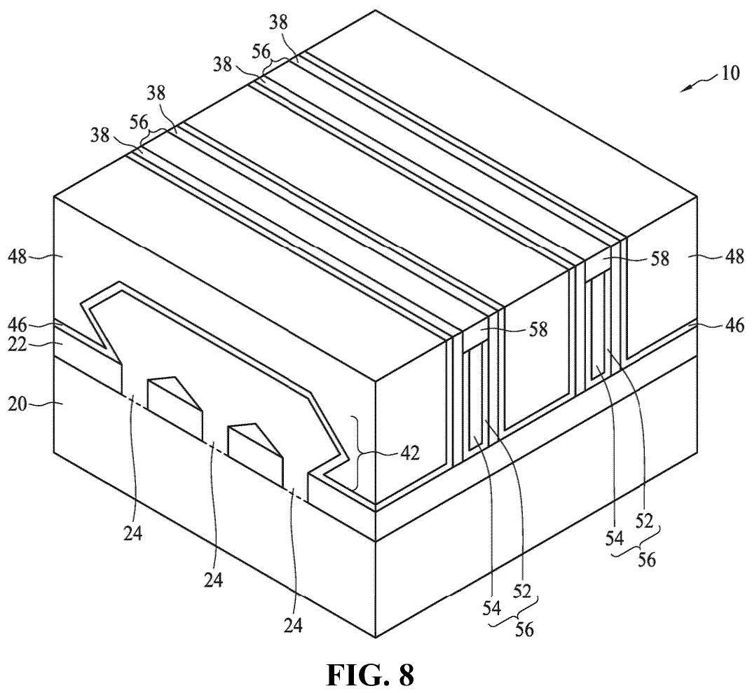

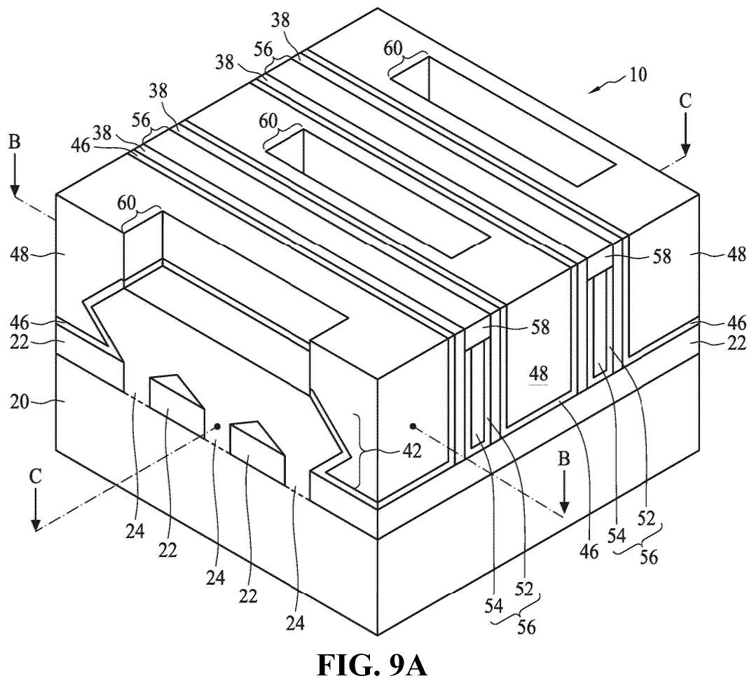

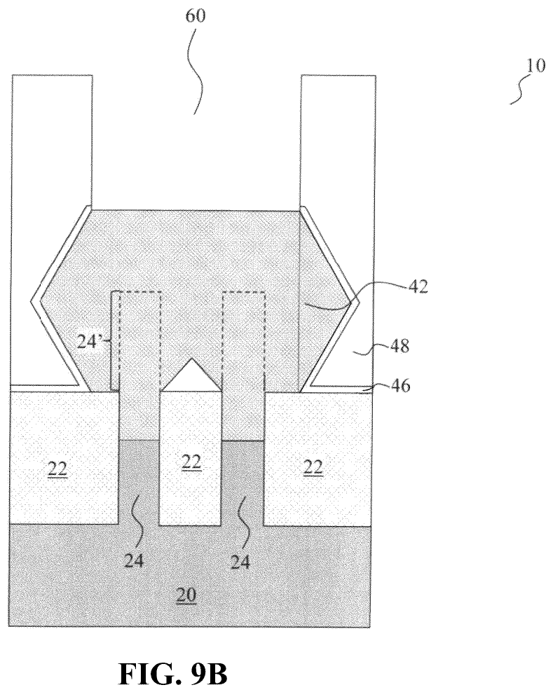

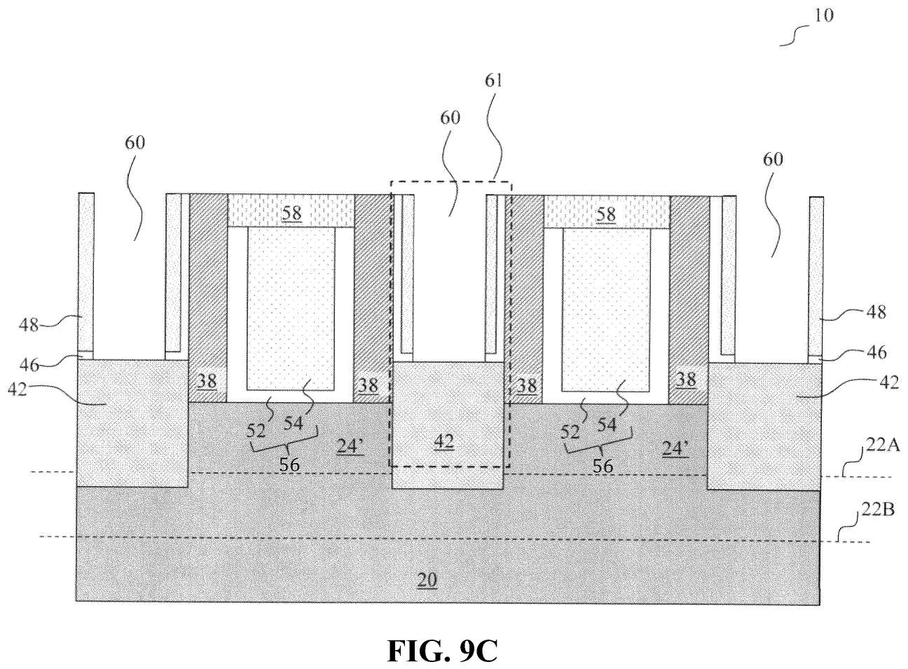

FIG. 9A illustrates the formation of source/drain contact openings 60. The respective process is illustrated as process 218 in the process flow 200 shown in FIG. 27. The formation of contact openings 60 include etching ILD 48 to expose the underlying portions of CESL 46, and then etching the exposed portions of CESL 46 to reveal epitaxy regions 42. In accordance with some embodiments, as illustrated in FIG. 9A, gate spacers 38 are spaced apart from the nearest contact openings 60 by some remaining portions of ILD 48. In accordance with other embodiments, the sidewalls of CESLs 46 are exposed to contact openings 60.

FIG. 9B illustrates a cross-sectional view showing the reference cross-section B-B in FIG. 9A. FIG. 9B illustrates a simplified view with two semiconductor strips 24. FIG. 9C illustrates a cross-sectional view showing the reference cross-section C-C in FIG. 9A. In FIG. 9C, the levels of the top surfaces 22A and bottom surfaces 22B of STI regions 22 are illustrated, and semiconductor fins 24′ are overtop surfaces 22A.

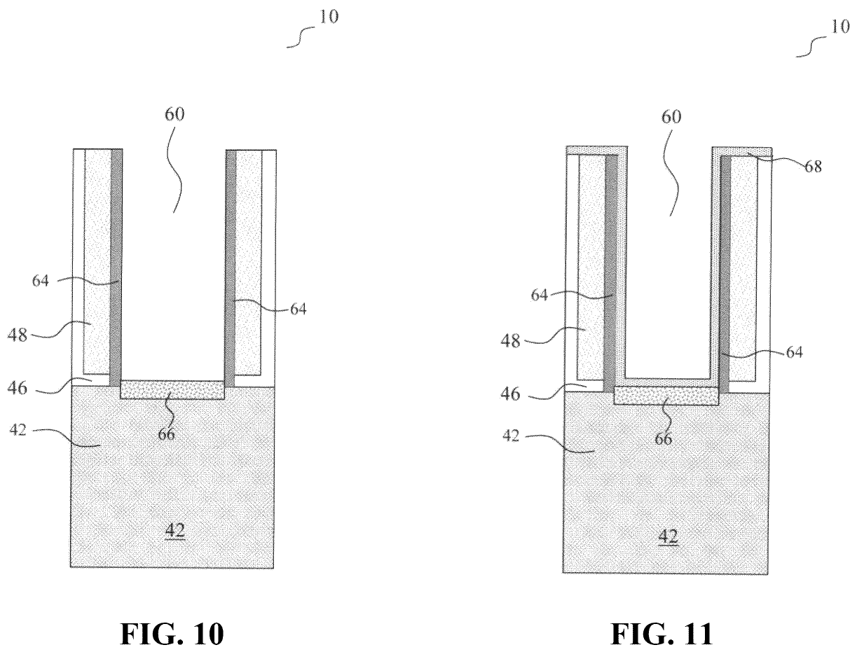

Subsequently illustrated FIGS. 10-15 illustrate the formation of source/drain contact spacers with reduced k values and contact plugs with reduced void in accordance with some embodiments. The illustrated cross-sections in FIGS. 10-15 are the same as the reference cross-section C-C in FIG. 9A, and illustrate the structure in region 61 in FIG. 9C.

Referring to FIG. 10, (source/drain) contact spacers 64 are formed. The respective process is illustrated as process 220 in the process flow 200 shown in FIG. 27. In accordance with some embodiments, the formation process includes depositing a conformal dielectric layer(s), and performing an anisotropic etching process to remove horizontal portions and leaving vertical portions as contact spacers 64. The deposition process may include a conformal deposition process such as an ALD process, a CVD process, or the like. In accordance with some embodiments, contact spacers 64 are formed of a nitride-based material such as SiN, while other materials such as SiON, SiCN, SiOCN, or the like may also be used. ILD 48, on the other hand, may be oxygen-based and may have higher oxygen atomic percentage than contact spacers 64. For example, ILD 48 may include SiO₂.

Silicide regions 66 may be formed on the top of source/drain regions 42. The formation process may be performed after (or before) the formation of contact spacers 64. The formation process may include depositing a metal layer comprising titanium, cobalt, or the like, or the combination thereof, performing an annealing process to form a metal silicide, and removing unreacted portions of the metal layer.

FIG. 11 illustrates the deposition of adhesion layer 68. The respective process is illustrated as process 222 in the process flow 200 shown in FIG. 27. In accordance with some embodiments, adhesion layer 68 is formed of or comprises titanium nitride, titanium silicon nitride TiSiN), or the like. The formation may include a conformal deposition process such as an ALD process, a CVD process, or the like.

Referring to FIG. 12, a treatment process 70 is performed. The respective process is illustrated as process 224 in the process flow 200 shown in FIG. 27. The treatment process 70 is used to treat and modify the surface features such as adhesion layer 68 and contact spacers 64, while deeper features deeper than contact spacers 64 are not treated. Silicide layers 66 may be treated partially (with the top portions treated) or entirely.

The treatment process 70 may include an oxidation process, a carbonation process, a reduction process (using plasma), and/or a thermal treatment process. The treatment process 70 may include one, two, three, or all four of these processes in any combination, which processes may be performed simultaneously, or may be performed sequentially. For example, the treatment process 70 may adopt a process gas containing oxygen and/or a process gas containing carbon, and hence the oxidation process and/or carbonation process may be performed. Also, hydrogen (H₂) may be added into the respective process gas when the oxidation process and/or carbonation process are performed, so that a reduction process is also performed. The treatment process 70 may also be performed at an elevated temperature or at room temperature, so that the treatment process may or may not include the thermal treatment process.

In accordance with some embodiments, the treatment process 70 may be performed using a process gas selected from O₂, O₃, CH₄, H₂, NO, N₂O, NO₂, NO₃, CO, CO₂, H₂O, and combinations thereof. The flow rate of the process gas may be in the range between about 1 sccm and about 10,000 sccm. The ratio of the flow rate of O₂ to the flow rate of the entire process gas may be in the range between about 0.2 percent and about 100 percent. The chamber pressure in the respective treatment chamber may be in the range between about 1 torr and about 50,000 torr.

The treatment process 70 may be performed with a plasma generated from the process gas, and the plasma may be direct plasma or remote plasma. In the treatment, the wafer temperature may be at room temperature (for example, about 20° C.). Alternatively, the wafer temperature may be higher than the room temperature, for example, in the range higher than about 20° C. and lower than about 400° C. Accordingly, the treatment process 70, when including plasma treatment, may also be a thermal treatment process. The plasma may be capacitively coupled plasma (CCP), inductively coupled plasma (ICP), microwave plasma, etc., and may be filtered to remove ions and leaving radicals for being used in the treatment, or not filtered.

Alternatively, the treatment process 70 may be a thermal treatment process, with no plasma being generated. The corresponding wafer temperature may be in the range between about 250° C. and about 400° C.

When the process gas includes an oxygen-containing gas (such as O₂, O₃, NO, N₂O, NO₂, NO₃, CO, CO₂, and/or H₂O), the treatment process 70 includes an oxidation process. When the process gas is a carbon-containing gas (such as CH₄, CO, and/or CO₂), the treatment process 70 includes a carbonation process. In addition, hydrogen (H₂) may be co-flow with the oxygen-containing gas and/or the carbon-containing gas. Accordingly, the treatment process 70 may also include a reduction process. Advantageously, the oxygen-containing gas and the carbon-containing gas tend to react with the dielectric materials such as contact spacers 64 and ILD 48, while the hydrogen (H₂) tends to react with metal-containing materials such as adhesion layer 68 and silicide regions 66. Accordingly, the effect of oxidation and carbonation of the metal-containing layers (such as adhesion layer 68 and silicide regions 66) is alleviated by the co-flow of the hydrogen.

In the treatment process 70, the process gas penetrates-through adhesion layer 68 to react with contact spacers 64, so that oxygen and carbon are added to contact spacers 64. This causes the increase in the atomic percentage of oxygen and/or carbon in contact spacers 64, and also causes the reduction (at least relatively) of the atomic percentage of nitrogen. Accordingly, the k value of contact spacers 64 is reduced. In accordance with some embodiments, before the treatment process 70, the k value of contact spacers 64 may be in the range between about 3.9 and about 7.0, while after the treatment process 70, the k value of contact spacers 64 may be reduced into the range between about 2.5 and about 5.0. After the treatment process 70, contact spacers 64 may also be porous, and hence are low-k dielectric layers, and may comprise SiON, SiOCN, SiCN, SiOCH, SiOₓ, SiCO, or the like.

Also, when the atomic percentage ratio O/N before the treatment process 70 is lower than about 1.0 (for example, in the range between about 0.9 and about 1.0 or lower than about 0.9), after the treatment, the atomic percentage ratio O/N may be increased to be greater than about 1.1 or higher.

In accordance with some embodiments, the entire contact spacers 64 are treated. In accordance with alternative embodiments, the treatment is shallow, and hence the sub layer (an outer portion) 64A is treated more, and has higher oxygen atomic percentage (and/or carbon atomic percentage) than sub layer 64B (an inner portion). Furthermore, the sub layer 64A may have a lower k value than sub layer 64B. Dashed lines are shown between sub layers 64A and 64B to indicate that different portions of contact spacers 64 may have different oxygen and/or carbon atomic percentages, or the entirety of contact spacers 64 may have the same atomic percentages of oxygen and/or carbon.

In accordance with some embodiments, after the treatment process 70, a reduction process 72 is performed. The respective process is illustrated as process 226 in the process flow 200 shown in FIG. 27. The reduction process 72 may be performed using hydrogen (H₂), without the use of oxygen-containing gas, carbon-containing gas, and nitrogen-containing gas. It is appreciated that in the treatment process 70, the adhesion layer 68 may be turned into an oxygen and/or carbon containing material, for example, including TiON, even if reduction process 70 may include (or does not include) hydrogen (H₂) to reduce the oxidation of adhesion layer 68. Also, native oxidation may occur. The reduction process 72 thus may reduce TiON back to TiN, which has lower resistance than TiON. Reduction process 72 may be a weak reduction process in that the reduction is controlled to be shallow, so that the reduction treats the surface layer such as adhesion layer 68, but is not strong enough to affect the underlying layer such as contact spacers 64. Alternatively stated, in the reduction process 72, contact spacers 64 may not be treated.

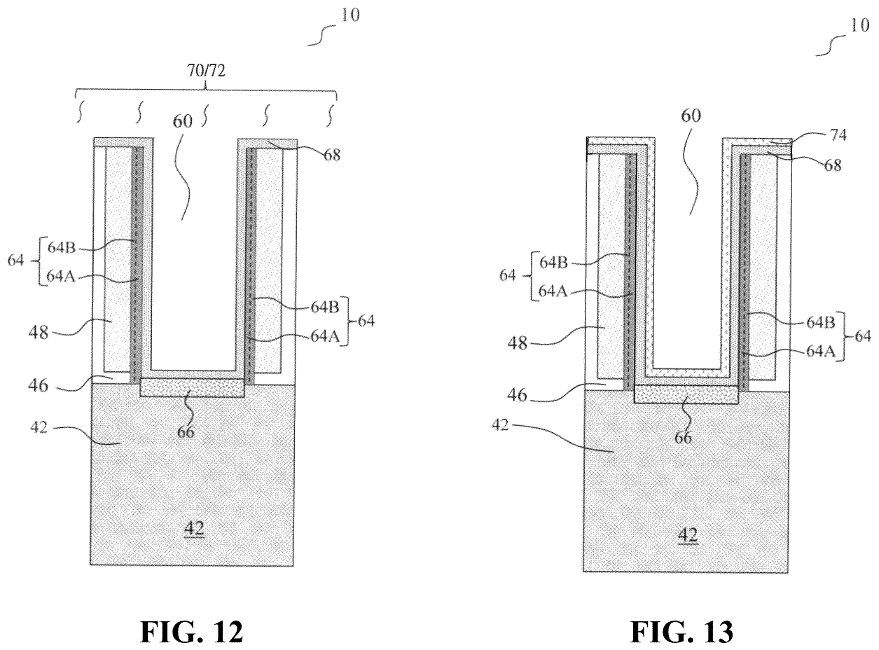

Referring to FIG. 13, metal barrier 74 (also referred to as a metal liner or a metal seed layer) is deposited. The respective process is illustrated as process 228 in the process flow 200 shown in FIG. 27. In accordance with some embodiments, metal barrier 74 is formed of or comprises tungsten, cobalt, or the like. The formation process may include, for example, Physical Vapor Deposition (PVD) or a like method.

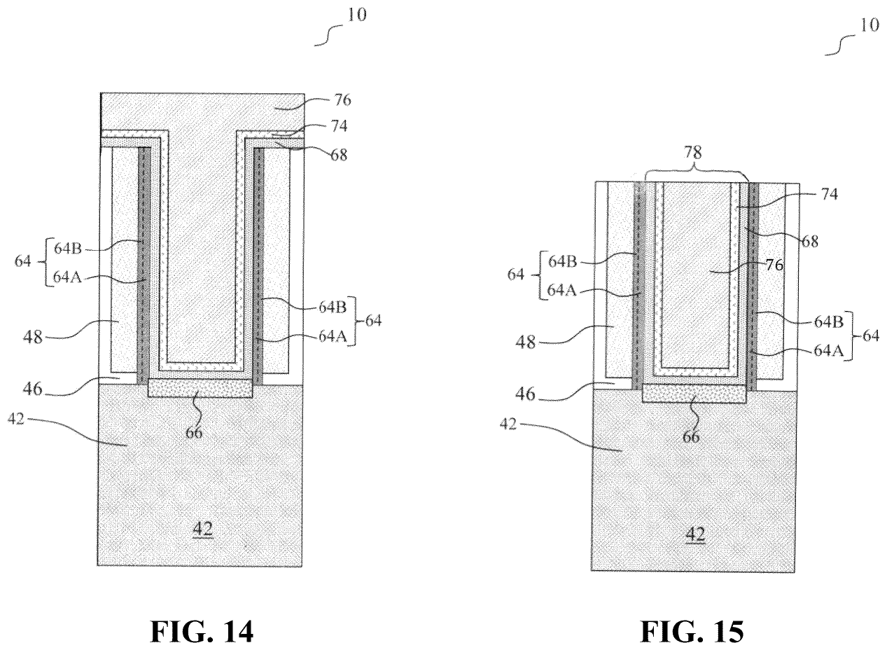

FIG. 14 illustrates the filling of opening 62 with a metallic material 76 such as tungsten, cobalt, or the like through a deposition process. The respective process is illustrated as process 230 in the process flow 200 shown in FIG. 27. Metallic material 76 may the same as or different from the material of metal barrier 74. Accordingly, metallic material 76 and metal barrier 74 may be, or may not be, distinguishable from each other. The deposition process of metallic material 76 may be performed using a conformal deposition process such as ALD, CVD, or the like.

After the deposition, a planarization process such as a CMP process or a mechanical grinding process is performed to remove excess portions of the deposited layers over ILD 48. The respective process is illustrated as process 232 in the process flow 200 shown in FIG. 27. Accordingly, contact plug 78 is formed, as shown in FIG. 15. Contact plug 78 includes adhesion layer 68, metal barrier 74, and metallic material 76.

In the structure as shown in FIG. 15, since contact spacers 64 have reduced k values due to the treatment process 7o, the parasitic capacitance between source/drain contact plugs 78 and nearby features such as gate stacks is reduced. FinFET 100 is thus formed, and FIG. 23 illustrates a perspective view of FinFET 100 and the corresponding contact spacers 64 and source/drain contact plugs 78.

Experiment results have revealed that when treatment process 70 is weak (for example, with reduced plasma energy, shorter treatment time, and/or lower wafer temperature), the parasitic capacitance may be reduced by about 1 percent. While when treatment process 70 is strong, the parasitic capacitance may be reduced more, for example, by about 2 percent.

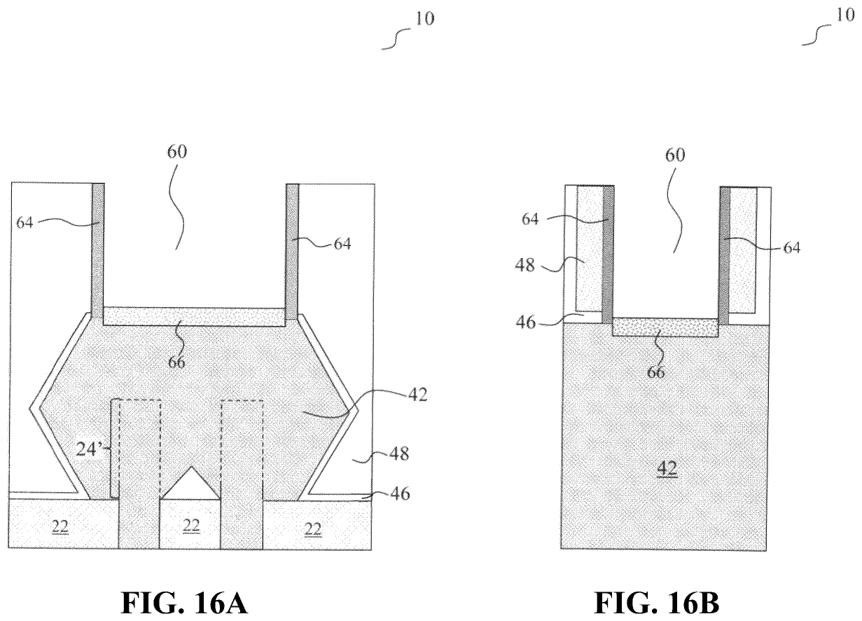

FIGS. 16A, 16B, 17A, 17B, 18A, 18B, 19A, 19B, 20A, 20B, 21A, 21B, 22A, and 22B illustrate the cross-sectional views of intermediate stages in the formation of contact spacers and contact plugs in accordance with alternatively embodiments. The corresponding process flow is also shown in the process flow 300 as shown in FIG. 28. These processes may replace the processes in FIGS. 10-15. Unless specified otherwise, the materials, the structures, and the formation processes of the components in these embodiments are essentially the same as the like components denoted by like reference numerals in the preceding embodiments. The details regarding the materials, the structures, and the formation processes provided in any of the embodiments throughout the description may be applied to any other embodiment whenever applicable.

The initial steps of these embodiments are essentially the same as shown in FIGS. 1-8 and FIGS. 9A, 9B, and 9C. FIGS. 16A and 16B illustrate the cross-sections B-B and C-C, respectively, as shown in FIG. 9A. Next, as also shown in FIGS. 16A and 16B, contact spacers 64 and silicide regions 66 are formed. The respective process is illustrated as process 302 in the process flow 300 shown in FIG. 28. The details have been discussed referring to FIG. 10, and hence are not repeated herein.

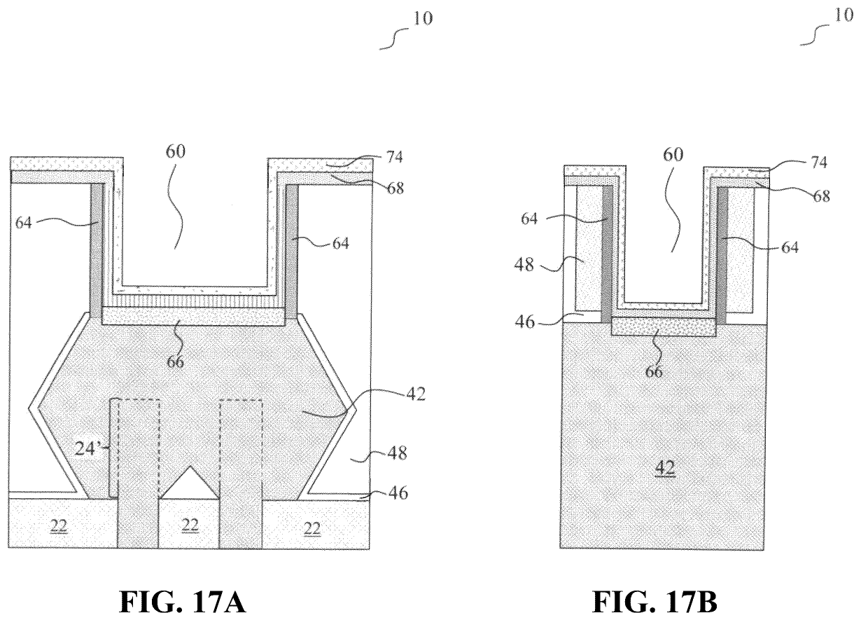

Referring to FIGS. 17A and 17B, adhesion layer 68 is deposited. The respective process is illustrated as process 304 in the process flow 300 shown in FIG. 28. Metal barrier 74 is then deposited. The respective process is illustrated as process 306 in the process flow 300 shown in FIG. 28. The formation details are essentially the same as discussed in the preceding embodiments, and are not repeated herein. Between the deposition of adhesion layer 68 and the deposition of metal barrier 74, no treatment process (such as the treatment process 70 and reduction process 72 as shown in FIG. 12) is performed.

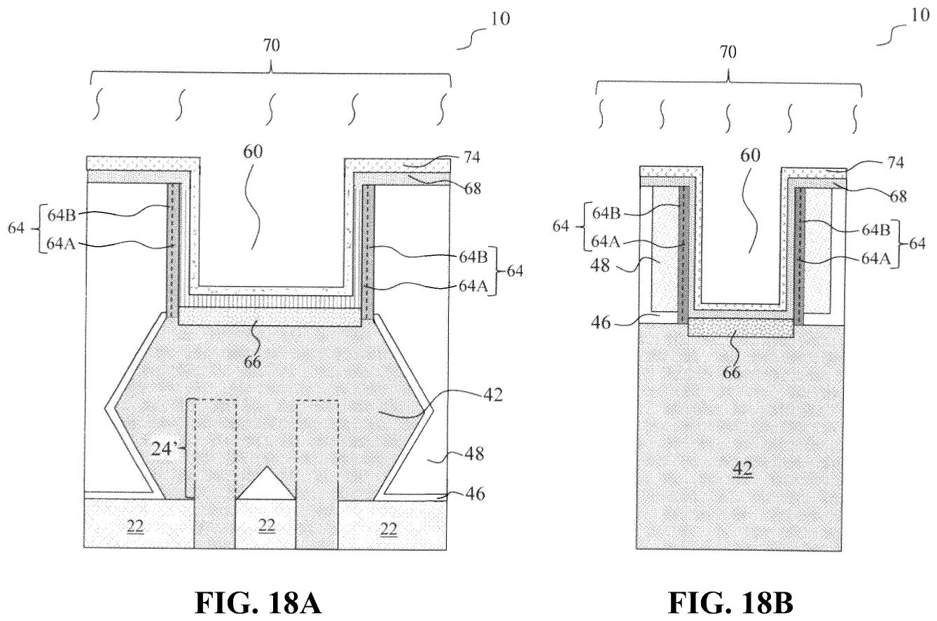

Next, as shown in FIGS. 18A and 18B, treatment process 70 is performed. The respective process is illustrated as process 308 in the process flow 300 shown in FIG. 28. The details of treatment process 70 are essentially the same as, and have been discussed referring to, FIG. 12, and hence are not repeated herein. Accordingly, oxidation process and/or carbonation process are performed on both of adhesion layer 68 and metal barrier 74, and hence these layers are converted into metal oxide layers and/or metal carbide layers. For example, adhesion layer 68 may be deposited as being a TiN layer (and may or may not include silicon), and may be converted into a TiON layer, a TiCN layer, or a TiOCN layer (including or not including Si). Metal barrier 74, when comprising tungsten, may be converted as a WO layer, a WC layer, or a WOC layer.

In addition, contact spacers 64 are also treated to have increased oxygen atomic percentage and/or carbon atomic percentage. The adding of oxygen and/or carbon also means that the nitrogen atomic percentage is reduced relatively. Accordingly, the k value of contact spacers 64 is lowered. Contact spacers 64, with the k value being lowered, may be, or may not be, a low-k dielectric layer. Also, contact spacers 64 may be treated shallow and have sub layers 64A treated more than subs layers 64B, or alternatively, have the entirety being treated to have the same oxygen and/or carbon atomic percentages.

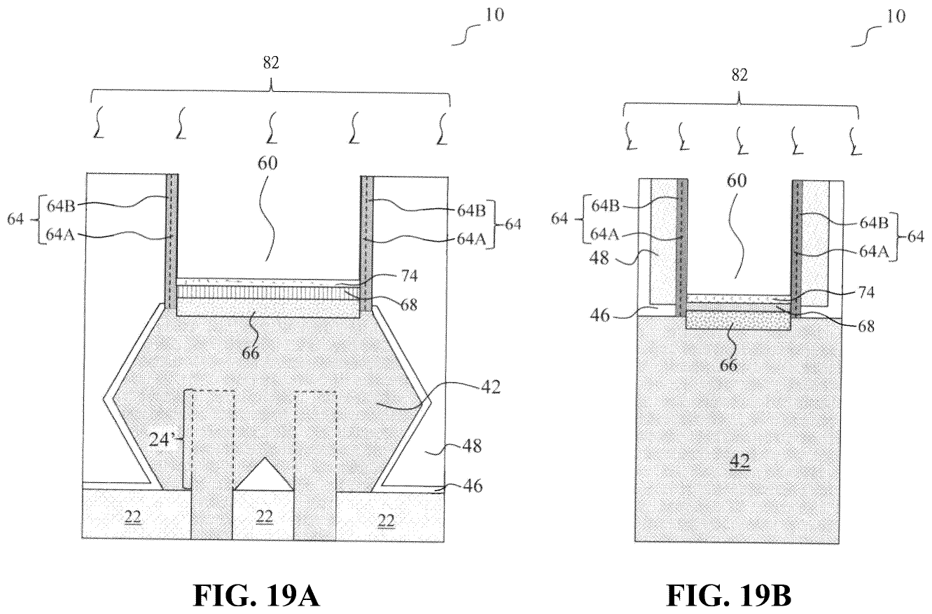

FIGS. 19A and 19B illustrate etch process 82, which is used to etch the top portions of adhesion layer 68 and metal barrier 74 over ILD 48 and the sidewall portions on the sidewalls of contact spacers 64, while leaving bottom portions at the bottoms of trenches 62. The respective process is illustrated as process 310 in the process flow 300 shown in FIG. 28. The previously performed treatment process 70 has converted adhesion layer 68 and metal barrier 74 as oxide and/or carbide layers, and hence enables the etching. The top portions are etched since these portions are deeply treated due to that they are outside of trenches. The sidewall portions are etched since these portions are thinner than the top portions and the bottom portions. The bottom portions of metal barrier 74 are thinned, but not removed entirely. The etch process 82 may be performed using a metal halide gas such as WF₆, or other process gases such as WCO, MoCO, or the like.

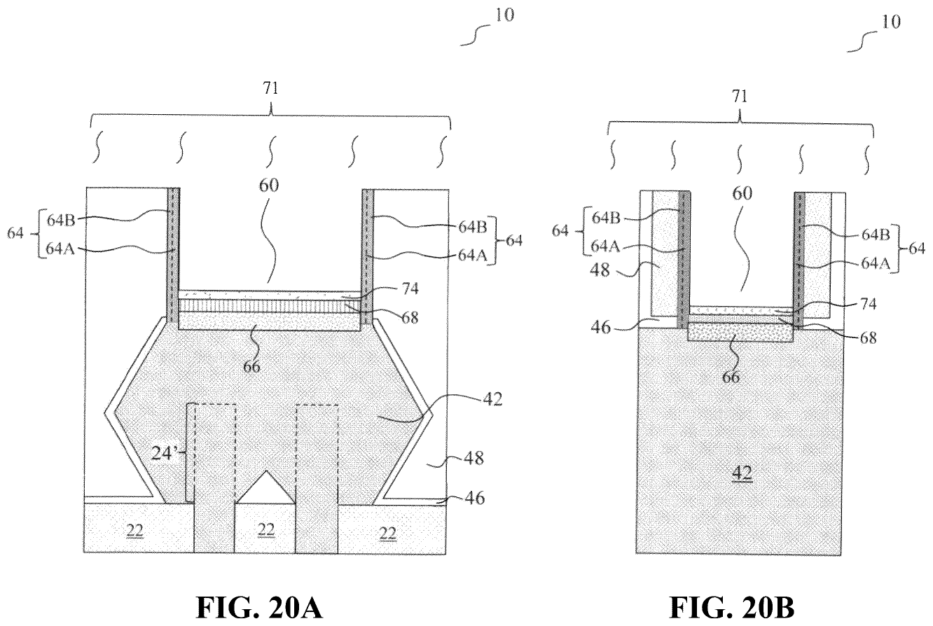

FIGS. 20A and 20B illustrate a passivation process 71 in accordance with some embodiments. The respective process is illustrated as process 312 in the process flow 300 shown in FIG. 28. This process may also be skipped in accordance with alternative embodiments. Accordingly, the process 312 is shown as being dashed in FIG. 28 to indicate that it may or may not be performed. It is appreciated that the etching process 82 may cause the exposed dielectric layers such as ILD 48 and contact spacers 64 to be damaged, and may cause dangling bonds to be formed on the exposed surfaces. Accordingly, the passivation process 71 may be performed to terminate the dangling bonds. In accordance with some embodiments, the passivation process 71 is performed using a process gas comprising both of oxygen (O₂) and hydrogen (H₂). The oxygen atoms are connected to and terminate the dangling bonds. The hydrogen has the function of reducing the exposed metal barrier 74 to reduce the oxidation effect of metal barrier 74.

The oxygen (O₂) tends to react with the dielectric materials such as contact spacers 64 and ILD 48, while the hydrogen (H₂) tends to react with metal-containing materials such as metal barrier 74, adhesion layer 68, and silicide regions 66. The oxidation/carbonation of the dielectric layers and the reduction of the metal-containing layers are thus performed simultaneously. Accordingly, the improvement of the contact spacers 64 and the reduction of the metal-containing layers are performed simultaneously. At least, the hydrogen reduces the oxidation/carbonation of the metal-containing layers.

In accordance with some embodiments, the processes as shown in FIGS. 20A and 20B are performed to passivate the surfaces of the exposed dielectric layers and to terminate dangling bonds. In accordance with alternative embodiments, the passivation process as shown in FIGS. 20A and 20B are skipped.

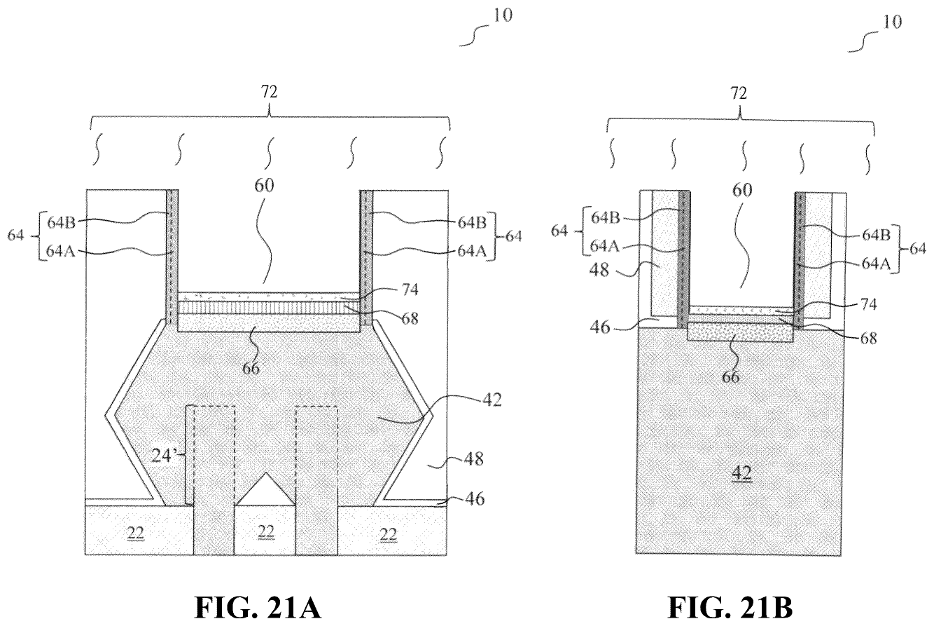

FIGS. 21A and 21B illustrate reduction process 72. The respective process is illustrated as process 314 in the process flow 300 shown in FIG. 28. The details of reduction process 72 may be essentially the same as what has been discussed referring to FIG. 12, and are not repeated herein. The reduction process 72 may reduce the metal barrier 74 (which have been oxidized and/or carbonized) back to elemental metal (rather than metal compounds). The adhesion layer 68 is also reduced, for example, back to TiN or TiSiN, so that its resistance is also reduced.

The treatment process 70, etching process 82, and the reduction process 72 as shown in FIGS. 21A and 21B collectively have the function of selectively etching the top portions and the sidewall portions, thus enabling the bottom-up formation of contact plugs. The respective process is illustrated as process 315 in the process flow 300 shown in FIG. 28.

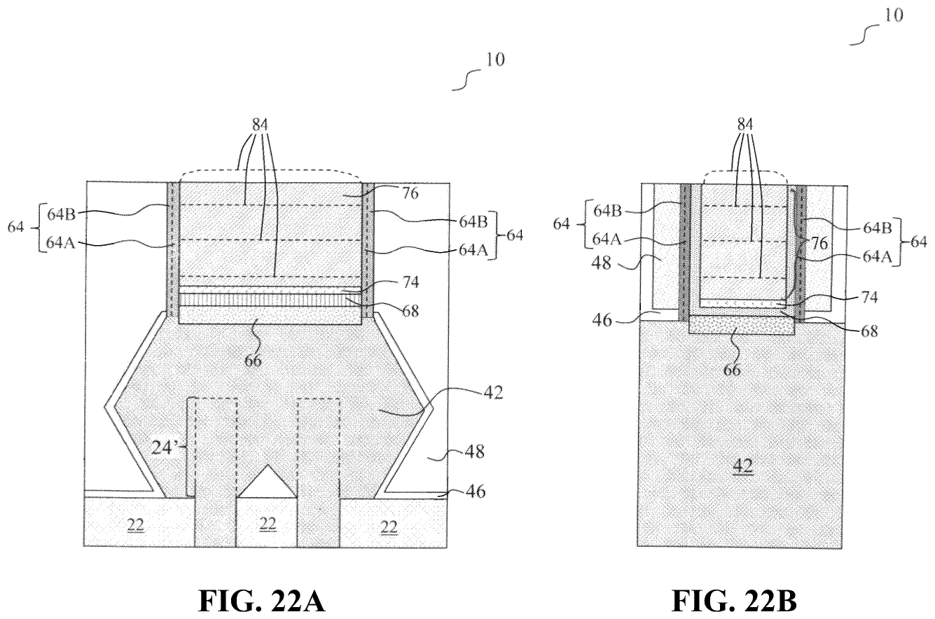

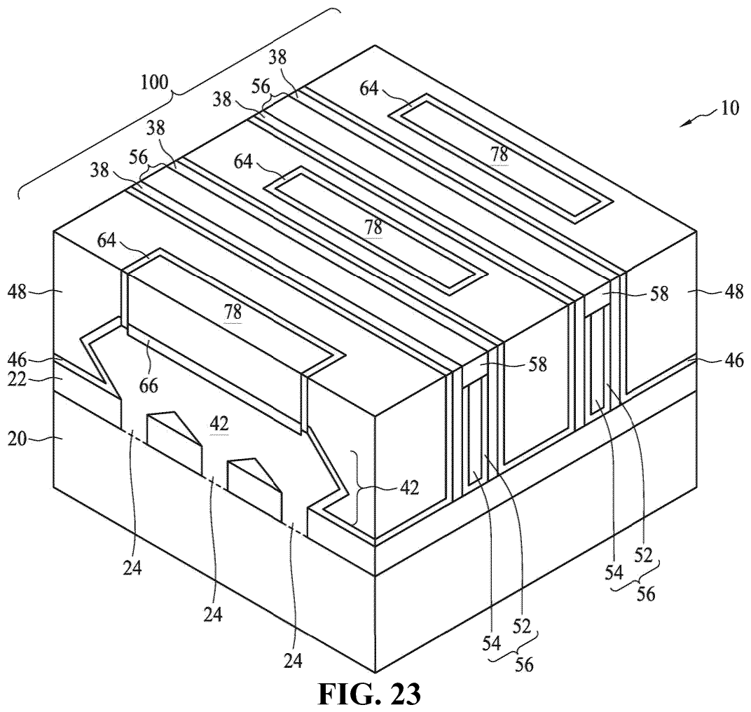

FIGS. 22A and 22B illustrate a deposition process to fill contact opening 60 with a metallic material 76, such as tungsten or cobalt. The respective process is illustrated as process 316 in the process flow 300 shown in FIG. 28. The deposition process is a selective deposition process, in which the metal is deposited selectively on metal barrier 74, but not on the exposed surface of the dielectric layers such as ILD 48 and contact spacers 64. Since contact spacers 64 have been treated, and thus have increased oxygen and/or carbon atomic percentage, the selectivity of the deposition process is increased, with the selectivity being the ratio of the deposition rate on metal barrier 74 to the deposition rate on dielectrics. Accordingly, the bottom-up deposition is achieved better, and voids are less likely to be formed in the resulting contact plug 78. Accordingly, the deposition of the metallic material 76 in accordance with these embodiments differ from the embodiments shown in FIG. 14, in which the deposition of metallic material 76 may be conformal.

The deposition of metallic material 76 may be performed using CVD, PECVD, or the like. Dashed lines 84 schematically illustrate the top surfaces of the deposited metal in different stages of the deposition process. After the deposition of the metallic material 76, a planarization process such as a CMP process or a mechanical grinding process is performed to remove excess portion of the deposited metallic material 76, and hence sourced/drain contact plug 78 is formed. The respective process is illustrated as process 318 in the process flow 300 shown in FIG. 28.

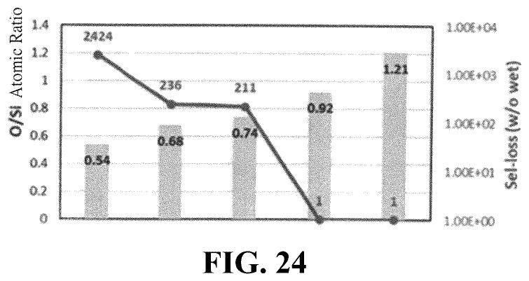

FIG. 24 illustrates some experiment results. The X-axis illustrates the degree of the treatment process 70, which is performed through oxidation in the illustrated example. From left to right, the oxidation is performed to increasingly greater degrees. The left Y-axis represents the O/Si atomic ratio, which increases when heavier oxidation is performed. It is noticed that with the oxidation being heavier, the O/Si atomic ratio increases from 0.54 (when no oxidation treatment is performed) to 0.68, to 0.74, to 0.92, and to 1.21. When no oxidation is performed, 2,424 contact plugs were found to have voids in a plurality of sample contact plugs. When heavier oxidation processes are performed, the number of voids in the same number of sample contact plugs are reduced to 236, to 211, and to 1. Since voids cause the increase in the contact plug, the experiment results indicate that the treatment process may reduce the resistance of the contact plugs

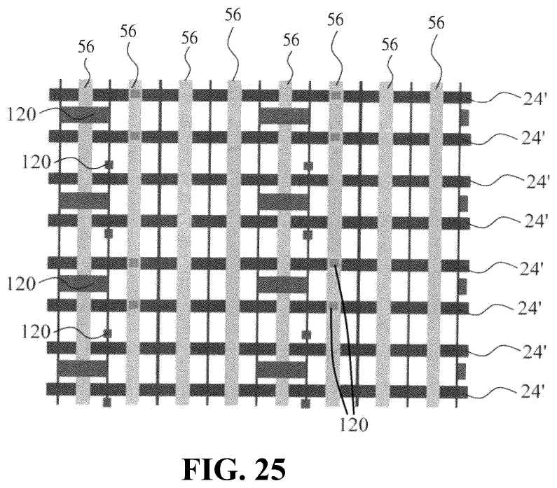

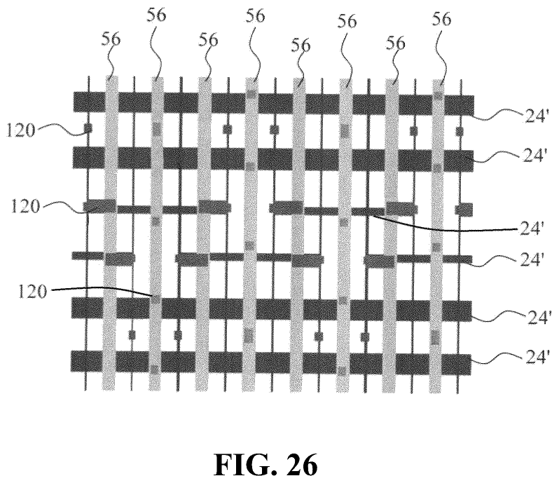

The contact plugs and spacers adopting embodiments of the present disclosure may be applied to all contact plugs in integrated circuits, which include, and are not limited to, source/drain contact plugs, gate contact plugs, the upper contact plugs over the source/drain contact plugs and the gate contact plugs, butted contact plugs, and the like. FIG. 25 illustrates a schematic top view of a logic circuit. The active regions (which may be semiconductor regions for semiconductor fins, semiconductor nanostructure, or the like) 24′ and gate stacks 56 are illustrated. A plurality of contact plugs 12o, which may represent the contact plugs 78 as aforementioned, and other contact plugs as aforementioned, are illustrated. FIG. 26 illustrates a schematic top view of a Static Random-Access Memory (SRAM) circuit. The contact plugs, vias, etc. in the illustrated top views may all be formed using the embodiments of the present disclosure, and are represented as 120.

The embodiments of the present disclosure have some advantageous features. By treating the contact spacers, which encircle contact plugs, the k values of the contact spacers are lowered, leading to the reduction of parasitic capacitance. Furthermore, the treatment improves the selectivity in the bottom-up deposition, which leads to the reduction (and sometimes the elimination) of voids, and leads to the reduction of the resistance of contact plugs.

In accordance with some embodiments of the present disclosure, a method comprises forming a contact spacer on a sidewall of an inter-layer dielectric, wherein the contact spacer encircles a contact opening; forming a silicide region in the opening and on a source/drain region; depositing an adhesion layer extending into the contact opening; performing a treatment process, so that the contact spacer is treated, wherein the treatment process is selected from the group consisting of an oxidation process, a carbonation process, and combinations thereof; depositing a metal barrier over the adhesion layer, depositing a metallic material to fill the contact opening; and performing a planarization process to remove excess portions of the metallic material over the inter-layer dielectric.

In an embodiment, the treatment process is performed after both of the adhesion layer and the metal barrier are deposited. In an embodiment, the method further comprises, after the treatment process, removing top portions and sidewall portions of the adhesion layer and the metal barrier, wherein the metallic material is filled starting from bottom portions of the adhesion layer and the metal barrier at a bottom of the contact opening. In an embodiment, the method further comprises, after the top portions and the sidewall portions of the adhesion layer and the metal barrier are removed, performing a passivation process on the contact spacer using a process gas comprising oxygen. In an embodiment, the process gas further comprises hydrogen (H₂). In an embodiment, the method further comprises, after the passivation process, performing a reduction process using hydrogen (H₂). In an embodiment, the treatment process is performed before the metal barrier is deposited.

In an embodiment, the treatment process is performed after the adhesion layer is deposited. In an embodiment, the method further comprises, after the treatment process, performing a reduction process using hydrogen (H₂). In an embodiment, before the treatment process, the contact spacer has a high dielectric constant, and after the treatment process, the contact spacer has a low-k dielectric constant. In an embodiment, the treatment process is performed through a plasma treatment process. In an embodiment, the treatment process is performed at an elevated wafer temperature. In an embodiment, the treatment process is performed using a treatment process gas selected from the group consisting of oxygen, carbon, and combinations thereof, and the treatment process gas further comprises hydrogen (H₂). In an embodiment, in the treatment process, an outer portion of the contact spacer is treated more than an inner portion of the contact spacer.

In accordance with some embodiments of the present disclosure, a method comprises forming a dielectric spacer on a sidewall of a dielectric layer, wherein the sidewall faces an opening in the dielectric layer, and the dielectric spacer encircles the opening; depositing a metal barrier extending into the opening and on the dielectric spacer; performing a treatment process on the metal barrier and the dielectric spacer, wherein a dielectric constant of the dielectric spacer is reduced by the treatment process; depositing a metallic material on the metal barrier, wherein the metallic material fills the opening; and performing a planarization process on the metallic material.

In an embodiment, the metal barrier and the metallic material comprise a same metal. In an embodiment, the method further comprises, before the metal barrier is deposited, depositing a metal nitride layer extending into the opening. In an embodiment, the method further comprises performing an etching process to remove a top portion and sidewall portions of the metal barrier that has been treated, with a bottom portion of the metal barrier at a bottom of the opening being left, and the metallic material is deposited in a bottom-up deposition process.

In accordance with some embodiments of the present disclosure, method comprises forming a dielectric spacer on a sidewall of a dielectric layer, wherein the dielectric spacer encircles an opening; depositing an adhesion layer extending into the opening and on the dielectric spacer; depositing a metal barrier extending into the opening and on the adhesion layer; performing a treatment process on the metal barrier, the adhesion layer, and the dielectric spacer; performing an etching process to remove some portions of the metal barrier and the adhesion layer to reveal the dielectric spacer; depositing a metallic material to fill the opening through a bottom-up deposition process; and performing a planarization process on the metallic material. In an embodiment, the method further comprises, after the etching process and before the metallic material is deposited, performing a passivation process on exposed surfaces of the dielectric spacer and the dielectric layer using an oxygen-containing gas and hydrogen (H₂); and performing a reduction process of the metal barrier and the adhesion layer using hydrogen (H₂).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming an adhesion layer comprising a metal nitride over a conductive feature;
performing a treatment process on the adhesion layer, wherein the treatment process is selected from the group consisting of an oxidation process, a carbonation process, and combinations thereof;
performing a reduction process on the adhesion layer using hydrogen (H₂);
depositing a metal layer over the adhesion layer; and
performing a planarization process to remove excess portions of the metal layer.

2. The method of claim 1, wherein the treatment process results in the adhesion layer to be converted as a metal oxynitride layer.

3. The method of claim 1, wherein the treatment process results in the adhesion layer to be converted as a metal oxycarbide layer.

4. The method of claim 1, wherein the adhesion layer comprises a portion in a contact opening, and the method further comprises:
before the adhesion layer is formed, forming a contact spacer in the contact opening.

5. The method of claim 4, wherein before the treatment process, the contact spacer has a first dielectric constant, and after the treatment process, the contact spacer has second dielectric constant lower than the first dielectric constant.

6. The method of claim 4, wherein after the treatment process, an outer portion of the contact spacer has a lower dielectric constant than an inner portion of the contact spacer.

7. The method of claim 1, wherein the adhesion layer is in physical contact with the conductive feature.

8. The method of claim 1, wherein the depositing the metal layer further comprises:
after the reduction process, depositing a metal barrier over the adhesion layer.

9. The method of claim 8, wherein the depositing the metal layer further comprises:
depositing a metallic material over the metal barrier.

10. The method of claim 1, wherein the treatment process comprises a plasma treatment process.

11. The method of claim 1, wherein the treatment process is performed at an elevated wafer temperature.

12. The method of claim 1, wherein a portion of the adhesion layer is removed through the planarization process.

13. A method comprising:
forming an adhesion layer on a sidewall of a dielectric layer, wherein the sidewall faces an opening in the dielectric layer, and the adhesion layer encircles the opening;
performing a treatment process on the adhesion layer using a process gas, wherein during the treatment process, a surface of the adhesion layer is exposed to the process gas;
after the treatment process, depositing a metal barrier extending into the opening and over the adhesion layer;
depositing a metallic material on the metal barrier, wherein the metallic material fills the opening; and
performing a planarization process on the metallic material.

14. The method of claim 13, wherein the treatment process is performed using process gases selected from the group consisting of oxygen, carbon, and combinations thereof.

15. The method of claim 14, wherein the process gases comprise oxygen.

16. The method of claim 14, wherein the process gases comprise carbon.

17. The method of claim 13, wherein the metal barrier and the metallic material comprise a same metal.

18. A method comprising:
forming a dielectric spacer on a sidewall of a dielectric layer, wherein the dielectric spacer encircles an opening;
depositing an adhesion layer in the opening and over the dielectric spacer;
after the adhesion layer is deposited, oxidizing the adhesion layer to comprise a metal oxide;
performing a reduction process to reduce an oxygen atomic percentage in the adhesion layer that comprises the metal oxide;
depositing a metallic material to fill the opening, wherein the metallic material is deposited over the adhesion layer; and
performing a planarization process on the metallic material.

19. The method of claim 18, wherein the adhesion layer comprises a metal nitride layer, and wherein the metal oxide comprises a metal oxynitride, and the reduction process further converts the adhesion layer back to the metal nitride layer.

20. The method of claim 18, wherein in the oxidizing the adhesion layer, carbon is further incorporated into the adhesion layer.
